(19) United States
(12) Patent Application Publication
(10) Pub. No.: US 2017/0283927 A1
(43) Pub. Date: Oct. 5, 2017

(54) METHOD FOR THE DETERMINATION OF THE REPRESENTATIVE HOMOTOP OF A BINARY METALLIC NANOPARTICLE (AxB1-x)N AND METHOD FOR MANUFACTURING THE CORRESPONDING NANOPARTICLE

(71) Applicants: UNIVERSITAT DE BARCELONA, Barcelona (ES); INSTITUCIÓ CATALANA DE RECERCA I ESTUDIS AVANÇATS, Barcelona (ES)

(72) Inventors: Sergey M. KOZLOV, Barcelona (ES); Konstantin M. NEYMAN, Barcelona (ES)

(73) Assignees: UNIVERSITAT DE BARCELONA, Barcelona (ES); INSTITUCIÓ CATALANA DE RECERCA I ESTUDIS AVANÇATS, Barcelona (ES)

(21) Appl. No.: 15/086,772

(22) Filed: Mar. 31, 2016

(51) Int. Cl. C22F 1/14; B22F 9/20; B22F 9/16; C23C 14/48; C25C 1/20; C22C 5/02; C22C 5/06; C22C 5/04; B22F 9/30; B22F 1/00

(52) U.S. Cl. CPC C22F 1/14; B22F 9/30; B22F 9/20; B22F 9/16; B22F 1/0018; C25C 1/20; C22C 5/02; C22C 5/06; C22C 5/04; C23C 14/48; B22F 2998/10; B22F 2304/054; B22F 2302/45; B22F 2301/10; B22F 2301/30; B22F 2301/255; B22F 2009/165; B22F 2202/01

(57) ABSTRACT

A method for the manufacturing a representative homotop of a binary metallic nanoparticle (AₓB₁₋ₓ)_{N} with a given composition AₓB₁₋ₓ, number of atoms N and shape, and at a given temperature, including generating a plurality of homotops, calculating an energy of the generate homotops using formula:

$${E}_{TOP} = {E}_{0} ( x , N ) + {ɛ}_{BOND}^{A \text{-} B} ( x ) {N}_{BOND}^{A \text{-} B} + {\sum }_{i} {ɛ}_{CORNER , i}^{A} ( x ) {N}_{CORNER , i}^{A} + {\sum }_{j} {ɛ}_{EDGE , j}^{A} ( x ) {N}_{EDGE , j}^{A} + {\sum }_{\{ LMN \}} {ɛ}_{\{ LMN \}}^{A} ( x ) {N}_{\{ LMN \}}^{A} \qquad ( 1 )$$

where E₀(x, N) is constant for a given particle, ε_{BOND}^{A-B}(x) is related to an energy gain caused by the mixing of both metals, N_{BOND}^{A-B} is a number of heteroatomic bonds, ε_{CORNER,i}^{A}(x) is an energy required for or gained from an exchange of an atom of type A on a corner of type i with an atom of type B in the nanoparticle interior, ε_{EDGE,j}^{A}(x) is an energy required for or gained from an exchange of an atom A on the nanoparticle edge of type j with an atom B in the nanoparticle interior, ε_{{LMN}}^{A}(x) is an energy required for or gained from an exchange of an atom A on a terrace on a nanoparticle facet with Miller indices {LMN} with an atom B in the nanoparticle interior, N_{CORNER,i}^{A}, N_{EDGE,j}^{A}, and N_{{LMN}}^{A} are numbers of atoms of type A on the respective corners, edges and terraces, determining the representative homotop, and manufacturing the nanoparticle.

### FIELD OF THE INVENTION

The invention relates to a method of manufacturing a binary metallic nanoparticle (AₓB₁₋ₓ)_{N} with a given composition AₓB₁₋ₓ, number of atoms N and shape, and possessing desired physical and/or chemical properties.

The invention relates to a method for the determination of the representative homotop of a binary metallic nanoparticle (AₓB₁₋ₓ)_{N} at a given temperature.

The invention has application to, e.g., manufacturing novel materials based on alloy nanoparticles, which are currently employed in catalysis, magnetic memory elements, medicine, pharmaceuticals and cosmetics.

### STATE OF THE ART

Nanoparticles (NPs) composed of atoms of more than one metal are often referred to as nanoalloys. They represent a lively research subject, thanks to their usage in catalysis, magnetic elements, optics, nanomedicine, etc. Properties of nanoalloys strongly depend not only on their geometric structure and size, but also on the composition. The latter makes nanoalloys much more tunable for tailored applications compared to monometallic particles.

Size and composition of bimetallic NPs are to a significant extent determined by preparation conditions. At the same time the geometric structure is affected by the relative thermodynamic stability of conceivable atomic arrangements of the two metals with more stable structures being easier to obtain. Computational search for the geometric structure and shape that yield the lowest energy for a given NP size and composition is a global optimization problem (see R. Ferrando, J. Jellinek and R. L. Johnston, Chem. Rev., 2008, 108, 845-910, cited below). Although numerous techniques have been developed to treat this extremely difficult problem, even nowadays global optimization of only relatively small particles is feasible.

A part of the global optimization problem is the search for the lowest-energy chemical ordering, that is, the location of atoms of different metals within a given geometric structure (i.e., a given crystal lattice). Chemical ordering governs such NP properties as surface composition and electronic structure, which are crucial for surface reactivity and heterogeneous catalysis. A rich variety of chemical ordering patterns can be found in nanoalloys: from ordered phases and solid solutions through core-shell and multishell arrangements to phase-separated quasi-Janus particles. As a rule, strong heteroatomic bonds and charge transfer between atoms of various metals favor well-mixed structures, while significant differences in atomic sizes and surface energies of the metals facilitate surface segregation. Despite that recent advances in electron microscopy techniques have allowed the visualization of individual atoms in bimetallic NPs, it is still hard to derive three-dimensional chemical ordering solely based on experimental data. Therefore, determining the most thermodynamically stable chemical ordering computationally is of great importance.

This task is extremely difficult, because the number of possible inequivalent arrangements of atoms of different types within a given geometric structure (i.e. the number of the so-called homotops) is enormously big. For instance, for a binary alloy particle consisting of N atoms, A_{Y}B_{N-Y}, the total number of homotops is

$$\frac{N !}{Y ! ( N - Y ) !} ,$$

which for Y=N/2 is approximately 2^{N+1/2}/\sqrt{πN}. This renders the complete exploration of the homotop landscape unfeasible already for NPs of a few dozens of atoms. At the same time, NPs that are relevant to chemical experiments and practical applications very often contain from several hundred to several thousand atoms.

In the present description and claims, the expression “homotop” of a nanoparticle will be used with the meaning “nanoparticle with the same geometric structure, number of atoms and composition, but different chemical ordering”.

In order to deal with this formidable problem of determining the chemical ordering, intelligent search algorithms combined with reliable energetic models are indispensable. Search algorithms that can explore the low-energy part of the homotop landscape have been developed. However, these algorithms can be used in the relevant size range of NPs only within simplified energetic models, since ab-initio search procedures are by far too tedious. Nowadays, state-of-the-art ab-initio searches are still limited to alloy particles with a few dozens of atoms, despite that much bigger NPs can be routinely calculated by density functional theory methods (DFT).

Simplified approaches to calculate energy of particles comprise atomistic interaction potentials and lattice models. Reliable interatomic potentials are available for some phase-separating systems and for certain systems making solid solutions, while their accuracy is often limited when dealing with systems forming ordered alloy phases. Generally speaking, the reliability of atomistic approaches for nanostructured materials is system-dependent and cannot be known a-priori. Rather, it needs to be examined for each case against higher-level, e.g. DFT, calculations. Furthermore, lattice models depend on a set of energetic parameters that are often fitted on bulk or surface quantities obtained by experiments or ab-initio calculations by ad-hoc procedures.

Document S. M. Kozlov, G. Kovács, R. Ferrando, K. M. Neyman, How to determine accurate chemical ordering in several nanometer large bimetallic crystallites from electronic structure calculations, Chem. Sci., 2015, 6, 3868-3880, describes a method that makes practical the determination of accurate chemical ordering in several nanometer large bimetallic crystallites. This new method allows to efficiently optimize the chemical ordering based solely on results of electronic structure (density functional) calculations. The results provide very intuitive understanding of, for instance, why gold and silver segregate on low coordinated sites in Pd₇₀Au₇₀ and Pd₇₀Ag₇₀ particles, while Pd₇₀Cu₇₀ exhibits matryoshka-like structure and Pd₇₀Zn₇₀ features Zn and Pd atoms arranged in layers. The document also establishes a protocol of the optimization of the chemical ordering in much larger Pd₇₃₂Au₇₃₁, Pd₇₃₂Ag₇₃₁, Pd₇₃₂Cu₇₃₁, and Pd₇₃₂Zn₇₃₁ nanocrystals, whose size around 4.4 nm is common for catalytic applications. This document is incorporated herein by reference.

Document M. Vorokhta, I. Khalakhan, M. Václav [symbol] a, G. Kovács, S. M. Kozlov, P. Kú\check{s}, T. Skála, N. Tsud, J. Lavková, V. Potin, I. Matolínová, K. M. Neyman, V. Matolína, Surface composition of magnetron sputtered Pt—Co thin film catalyst for proton exchange membrane fuel cells, Appl. Surf. Sci., 2016, 365, 245-251, describes investigation of magnetron sputtered Pt—Co thin film catalyst by both experimental and theoretical methods. Scanning electron microscopy and transmission electron microscopy experiments confirmed the nanostructured character of the catalyst. The surface composition of as-deposited and annealed at 773 K Pt—Co films was investigated by surface analysis techniques, such as synchrotron radiation photoelectron spectroscopy and X-ray photoelectron spectroscopy. Modeling based on density functional theory showed that the surface of 6 nm large 1:1 Pt—Co particles is almost exclusively composed of Pt atoms (>90%) at typical operation conditions and the Co content does not exceed 20% at 773 K, in agreement with the experimental characterization of such films annealed in vacuum. According to experiment, the density of valence states of surface atoms in Pt—Co nanostructures is shifted by 0.3 eV to higher energies, which can be associated with their higher activity in the oxygen reduction reaction. The changes in electronic structure caused by alloying are also reflected in the measured Pt 4f, Co 3p and Co 2p photoelectron peak binding energies. This document is incorporated herein by reference.

Document R. Ferrando, J. Jellinek, R. L. Johnston, Nanoalloys: From theory to applications of alloy clusters and nanoparticles, Chem. Rev., 2008, 108, 845-910, describes several methods for generating nanoalloys, experimental techniques for characterization of nanoalloys, theoretical framework and computational methods for studying nanoalloys, structural, optical and magnetic properties of nanoalloys, catalysis by nanoalloys, melting of nanoalloys and intermixing kinetics, freezing, growth and coalescence of nanoalloys. This document is incorporated herein by reference.

Document G. L. W. Hart, V. Blum, M. J. Walorski, A. Zunger, Evolutionary approach for determining first-principles Hamiltonians, Nat. Mater., 2005, 4, 391-394, describes the treatment of large cells or searches over millions of structure types with first-principles accuracy by ‘coarse-graining’ the many particle Schrödinger equation into ‘model Hamiltonians’ whose variables are configurational order parameters (atomic positions, spin and so on), connected by a few ‘interaction parameters’ obtained from a microscopic theory. In order to construct a truly quantitative model Hamiltonian, one must know just which types of interaction parameters to use, from possibly 10⁶-10⁸ alternative selections. It is shown how genetic algorithms, mimicking biological evolution (‘survival of the fittest’), can be used to distil reliable model Hamiltonian parameters from a database of first-principles calculations. This is demonstrated for a classic dilemma in solid-state physics, structural inorganic chemistry and metallurgy: how to predict the stable crystal structure of a compound given only its composition. This document is incorporated herein by reference.

Document S. Guo, S. Zhang, S. Sun, Tuning Nanoparticle Catalysis for the Oxygen Reduction Reaction, Angew. Chem. Int. Ed. 2013, 52, 8526-8544, highlights recent efforts in the development of Pt and non-Pt based NPs into advanced nanocatalysts for efficient oxygen reduction reaction (ORR) under fuel-cell reaction conditions. It first outlines the shape controlled synthesis of Pt NPs and their shape-dependent ORR. It also summarizes the studies of alloy and core-shell NPs with controlled electronic (alloying) and strain (geometric) effects for tuning ORR catalysis. It further provides a brief overview of ORR catalytic enhancement with Pt-based NPs supported on graphene and coated with an ionic liquid, and introduces some non-Pt NPs as a new generation of catalysts for ORR. The reported new syntheses with NP parameter-tuning capability should pave the way for future development of highly efficient catalysts for applications in fuel cells, metal-air batteries, and even in other important chemical reactions. This document is incorporated herein by reference.

Document S. M. Kozlov, K. M. Neyman, Catalysis from first principles: towards accounting for the effects of nanostructuring, Top. Catal., 2013, 56, 867-873, deals with an issue of density functional description of heterogeneous catalysts by nanoparticle models instead of still commonly employed slab models. Typically, active (metal) components are present in catalysts as nano-aggregates formed of many thousands atoms, remaining due to their size inaccessible even for modern first-principles computations. However, such species could be rather realistically represented by notably smaller computationally tractable model NPs, whose surface sites only marginally change the reactivity with increasing particle size. The presented results are mainly related to methane dehydrogenation on Pt catalysts, methanol decomposition on Pd catalysts and the composition of active sites on Pt/ceria catalysts. They document the feasibility of taking nanostructuring effects into account in density-functional modeling (at least for transition metals) and, more importantly, demonstrate that ignoring the nanoeffects in these systems leads to misrepresentation of their catalytic properties. This document is incorporated herein by reference.

Document T. Mueller, Ab initio determination of structure-property relationships in alloy nanoparticles, Phys. Rev. B, 2012, 86, 144201, presents a computational study on atomic ordering in 2-nm cuboctahedral Au—Pd nanoparticles. Equilibrium atomic structures, energies, and electronic surface d-band centers have been calculated across the entire range of compositions at different temperatures using a Bayesian approach to cluster expansions. The estimated prediction error in formation energies calculated by the cluster expansion, relative to density functional theory, is approximately 1 meV/atom. This prediction error would be low for a cluster expansion on a bulk material, and it is exceptionally low for a study of nanoparticles of this size. This result was accomplished by extending the Bayesian approach for cluster expansions to account for nonlocal, composition-dependent effects that might otherwise not be captured. For this system the Bayesian approach is estimated to be approximately five times as efficient as more common cluster selection techniques. This document is incorporated herein by reference.

In document L.-L. Wang, T. L. Tan, D. D. Johnson, Nanoalloy electrocatalysis: simulating cyclic voltammetry from configurational thermodynamics with adsorbates, Phys. Chem. Chem. Phys., 2015, 17, 28103-28111, the adsorption isotherms for alloyed nanoparticles (nanoalloys) with adsorbates is simulated in order to determine cyclic voltammetry (CV) during electrocatalysis. The effect of alloying on nanoparticle adsorption isotherms is provided by a hybrid-ensemble Monte Carlo simulation that uses the cluster expansion method extended to non-exchangeable coupled lattices for nanoalloys with adsorbates. Exemplified here for the hydrogen evolution reaction, a 2-dimensional CV is mapped for Pd—Pt nanoalloys as a function of both electrochemical potential and the global Pt composition, and shows a highly non-linear alloying effect on CV. Detailed features in CV arise from the interplay among the H-adsorption in multiple sites that is closely correlated with alloy configurations, which are in turn affected by the H-coverage. The origins of specific features in CV curves are assigned. The method provides a more complete means to design nanoalloys for electrocatalysis. This document is incorporated herein by reference.

Document S. M. Kozlov, K. M. Neyman, Insights from methane decomposition on nanostructured palladium, J. Catal., 2016, 337, 111-121, deals with such fundamental questions related to how nanostructuring affects activity of heterogeneous catalysts, as if nanoparticle edges have the same catalytic properties as steps on single-crystal surfaces, how much does the increased structural flexibility of nanoparticles contribute to their activity or how do reaction barriers depend on the nanoparticle size. These questions are addressed regarding an exemplary reaction sequence of complete methane dehydrogenation. Using density functional theory methods energy profiles of this reaction are calculated on edges of 1.2 nm large Pd₇₉ and 1.6 nm large Pd₁₄₀ particles as well as on Pd (111) and steps on Pd (211) single-crystal surfaces. The barriers of the two slowest reaction steps, CH₄→CH₃+H and CH→C+H, notably decrease in the following series of substrates: Pd (111)>Pd (211)>Pd₁₄₀>Pd₇₉. Importantly, these barriers differ by ≧20 kJ/mol on Pd₁₄₀ and Pd (211), whereas the differences between the barriers on Pd (111) and Pd (211) are only ≦11 kJ/mol. Also, the structural flexibility contributes to higher reactivity several times stronger for Pd₇₉ than for Pd (111). All calculated elementary steps follow Brønsted-Evans-Polanyi relationships. This document advances the understanding of heterogeneous catalysis by shedding light on several fundamental questions concerning structure-property relationships in nanostructured catalysts. This document is incorporated herein by reference.

Document C. J. Cramer, D. G. Truhlar, Density functional theory for transition metals and transition metal chemistry, Phys. Chem. Chem. Phys., 2009, 11, 10757-10816, introduces density functional theory and reviews recent progress in its application to transition metal chemistry. Topics covered include local, meta, hybrid, hybrid meta, and range-separated functionals, band theory, software, validation tests, and applications to spin states, magnetic exchange coupling, spectra, structure, reactivity, and catalysis, including molecules, clusters, nanoparticles, surfaces, and solids. This document is incorporated herein by reference.

Document L. Zhang, R. M. Anderson, R. M. Crooks, G. Henkelman, Correlating Structure and Function of Metal Nanoparticles for Catalysis, Surf. Sci., 2015, 640, 65-72, summarizes several studies correlating the structure and function of nanoparticle catalysts. Three types of alloy nanoparticles are considered, random alloy, core@shell and alloy-core@shell structures. In the first two cases, the focus is to build theoretical models to understand previous experimental results. In the latter case, calculations play a greater role in leading the development of nanoparticle catalysts. It demonstrates that iteration between theory and experiment can facilitate an understanding of nanoparticle catalysts and reduce the time and effort involved in the design of new catalysts. This document is incorporated herein by reference.

Document D. Wang, Y. Li, Bimetallic Nanocrystals: Liquid-Phase Synthesis and Catalytic Applications, Adv. Mater., 2011, 23, 1044-1060, emphasizes the importance of bimetallic nanocrystals (NCs) with core/shell, heterostructure, or intermetallic and alloyed structures, as they are expected to display not only a combination of the properties associated with two distinct metals, but also new properties and capabilities due to a synergy between the two metals. More importantly, bimetallic NCs usually show composition-dependent surface structure and atomic segregation behavior, and therefore more interesting applied potentials in various fields including electronics, engineering, and catalysis. The document highlights the recent progress in the chemical synthesis of bimetallic NCs. The control over morphology, size, composition, and structure of bimetallic NCs as well as the exploration of their properties and applications are discussed. This document is incorporated herein by reference.

Document Y. Saito, The Monte Carlo simulation of microstructural evolution in metals, Mater. Sci. Eng. A, 1997, 223, 114-124, introduces the Monte Carlo simulations and surveys recent developments in mesoscale and atomistic Monte Carlo simulation based on statistical mechanics. Fundamentals of simulation techniques and dynamical and topological behaviors of microstructural evolutions are described. The simulation of grain growth based on Potts' model is described as a mesoscale simulation example. Kinetics of interface migration can be traced by flipping of spin variables. Scaling behaviors of domain structure are given by cluster analysis method. As an atomistic scale simulation example, the ordering of f.c.c, to L12 structure in Ni base alloy is introduced. Ordering kinetics is controlled by a direct exchange of neighboring single atoms. The ordering kinetics, the temporal evolution of atomic arrangement, the site occupancy of alloying elements are predicted by the model. This document is incorporated herein by reference.

### SUMMARY OF THE INVENTION

The object of the invention is to overcome drawbacks outlined in the description of the state of the art. This objective is achieved by a method of manufacturing (or engineering) a binary metallic nanoparticle (AₓB₁₋ₓ)_{N} comprising:

[a] determining the representative homotop for each of a plurality of binary metallic nanoparticles (AₓB₁₋ₓ)_{N} with different compositions AₓB₁₋ₓ, numbers of atoms N or shapes and at a given temperature, by:
[a1] selecting one of the plurality of binary metallic nanoparticles;
[a2] generating a plurality of homotops of the nanoparticle of step [a1];
[a3] calculating an energy of the generated homotops of step [a2] using formula (1):

$${E}_{TOP} = {E}_{0} ( x , N ) + {ɛ}_{BOND}^{A \text{-} B} ( x ) {N}_{BOND}^{A \text{-} B} + {\sum }_{i} {ɛ}_{CORNER , i}^{A} ( x ) {N}_{CORNER , i}^{A} + {\sum }_{j} {ɛ}_{EDGE , j}^{A} ( x ) {N}_{EDGE , j}^{A} + {\sum }_{\{ LMN \}} {ɛ}_{\{ LMN \}}^{A} ( x ) {N}_{\{ LMN \}}^{A} \qquad ( 1 )$$

wherein
E₀(x, N) is constant for a given particle (AₓB₁₋ₓ)_{N},
ε_{BOND}^{A-B}(x) is related to an energy gain caused by the mixing of both metals A, B,
N_{BOND}^{A-B} is a number of heteroatomic bonds;
ε_{CORNER,i}^{A}(x) is an energy required for or gained from an exchange of an atom of type A on a corner of type i of the nanoparticle with an atom of type B in an interior of the nanoparticle, given that N_{BOND}^{A-B} remains constant,
ε_{EDGE,j}^{A}(x) is an energy required for or gained from an exchange of an atom of type A on an edge of type j of the nanoparticle with an atom of type B in the nanoparticle interior, given that N_{BOND}^{A-B} remains constant,
ε_{{LMN}}^{A}(x) is an energy required for or gained from an exchange of an atom of type A on a terrace on a nanoparticle facet with Miller indices {LMN} of the nanoparticle with an atom of type B in the nanoparticle interior, given that N_{BOND}^{A-B} remains constant,
N_{CORNER,i}^{A}, N_{EDGE,j}^{A}, and N_{{KLM}}^{A} are numbers of atoms of type A on corners of type i, edges of type j and terraces on nanoparticle facets with Miller indices {LMN}, respectively;
[a4] determining the representative homotop of the nanoparticle of step [a1],
[a5] repeating steps [a1] to [a4] for each of the plurality of binary metallic nanoparticles,
[b] determining the physical and/or chemical properties of the resulting representative homotops,
[c] selecting one of said representative homotops having the desirable combination of composition, number of atoms and shape, and
[d] manufacturing of the corresponding binary metallic nanoparticle, wherein the manufacturing includes forming the nanoparticle according to the selected combination of composition, number of atoms and shape.

Preferably the manufacturing includes forming the nanoparticle by using at least one of molecular beams, chemical reduction, thermal decomposition of transition-metal complexes, ion implantation, electrochemical synthesis, radiolysis, sonochemical synthesis, biosynthesis, co-deposition of two metals on a support, co-precipitation of two metals from a solution or annealing.

The determination of the physical properties (including magnetic and optical properties) and/or chemical properties (including catalytic, adsorption and absorption properties) can be done by a skilled person, for example by using widespread electronic structure simulation methods based on density functional theory. Other possible available methods are, for example, “dimer” and “nudged elastic band” methods for prediction of catalytic and chemical properties using transition state theory, time-dependent density functional theory methods for prediction of optical properties, and relativistic density functional theory methods for prediction of magnetic properties.

It is usually straightforward to control composition of manufactured alloy nanoparticles; however, it is challenging to manufacture nanoparticles with the exact size (for example, 140 atoms or 1.6 nm). State-of-the-art preparation techniques yield nanoparticles with the linear size distribution of +−10% (that is, +−30% in the number of atoms). More common techniques yield nanoparticles with the linear size distribution of +−30% (that is, variation in the number of atoms by a factor of 2). However, such wide size distributions among prepared nanoparticles are suitable for most of the chemical applications. Typically, one needs to change the linear size of nanoparticles by a larger extent to see a notable effect on the NP properties.

The nanoparticle structure predicted by the method of the invention corresponds to thermodynamic equilibrium, which is achieved at high temperature. That is, the predicted structure can be prepared, for example, by high temperature annealing of nanoparticles prepared by almost any method. This procedure is possible only when material containing nanoparticles is stable at high temperatures. Most such materials contain also nanoparticle support or ligand molecules surrounding nanoparticles in order to prevent merging of nanoparticles into much larger aggregates lacking nanostructuring even at moderate temperatures. In order for the material to be stable at high temperatures nanoparticle support or ligands should be also stable at high temperatures. Therefore, preferably the manufacturing method comprises an annealing step, performed at a predetermined annealing temperature and on a support thermally stable at the annealing temperature and/or the manufacturing method comprises an annealing step, performed at a predetermined annealing temperature and surrounded by ligands thermally stable at the annealing temperature.

Another object of the invention is a method for determining a representative homotop of a binary metallic nanoparticle (AₓB_{1*x})_{N} with a given composition AₓB₁₋ₓ, number of atoms N and shape, and at a given temperature, comprising:

generating a plurality of homotops;
calculating an energy of the generated homotops using formula (1):

$${E}_{TOP} = {E}_{0} ( x , N ) + {ɛ}_{BOND}^{A \text{-} B} ( x ) {N}_{BOND}^{A \text{-} B} + {\sum }_{i} {ɛ}_{CORNER , i}^{A} ( x ) {N}_{CORNER , i}^{A} + {\sum }_{j} {ɛ}_{EDGE , j}^{A} ( x ) {N}_{EDGE , j}^{A} + {\sum }_{\{ LMN \}} {ɛ}_{\{ LMN \}}^{A} ( x ) {N}_{\{ LMN \}}^{A} \qquad ( 1 )$$

wherein
E₀(x, N) is constant for a given particle (AₓB₁₋ₓ)_{N},
ε_{BOND}^{A-B} is related to an energy gain caused by mixing of both metals A, B,
N_{BOND}^{A-B} is a number of heteroatomic bonds;
ε_{CORNER,i}^{A}(x) is an energy required for or gained from an exchange of an atom of type A on a corner of type i of the nanoparticle with an atom of type B in the interior of the nanoparticle, given that N_{BOND}^{A-B} remains constant,
ε_{EDGE,j}^{A}(x) is an energy required for or gained from an exchange of an atom of type A on an edge of type j of the nanoparticle with an atom of type B in the nanoparticle interior, given that N_{BOND}^{A-B} remains constant,
ε_{{LMN}}^{A}(x) is an energy required for or gained from an exchange of an atom of type A on the terrace on a nanoparticle facet with Miller indices {LMN} with an atom of type B in the nanoparticle interior, given that N_{BOND}^{A-B} remains constant, and
wherein N_{CORNER,i}^{A}, N_{EDGE,j}^{A}, and N_{{KLM}}^{A} are numbers of atoms of type A on corners of type i, edges of type j and terraces on nanoparticle facets with Miller indices {LMN}, respectively, and determining the representative homotop.

In general, the lowest energy homotop is the most probable homotop at low temperatures. At higher temperatures more disordered structures also become probable (representative). The method according to the invention allows the determination of the most representative structure (homotop) at any temperature below temperatures when the melting of nanoparticles starts that, in the present description and claims has been named the “representative homotop”. More precisely, the “representative homotop” is the homotop, whose structural properties are the closest to average properties of ensemble of homotops in thermodynamic equilibrium at a given temperature.

The present invention proposes a general and systematic method for developing lattice models that aims at transferring ab-initio or DFT level of accuracy to NP sizes that are relevant to experiments and practical applications. This method is based on the analysis of energy related to topological degrees of freedom, E_{TOP}, which is reminiscent of model Hamiltonians in the Ising model or the cluster expansion method (see G. L. W. Hart, V. Blum, M. J. Walorski and A. Zunger, Nat. Mater., 2005, 4, 391-394). Topological degrees of freedom used in the present invention take into account 1) the formation of heteroatomic bonds, 2) the different coordination of atoms in different positions of a NP, and 3) the possible tetragonal distortion in L1₀ alloys. The parameters in the energy expression for each NP size, shape and composition are derived by a rigorous fitting procedure based on energies, E_{ES}, from a limited set of density functional (electronic structure) calculations for NPs of the same size, shape and composition. The inherently physical origin of the fitted parameters allows one to directly rationalize the nature of binding in the considered alloys. The accuracy and precision of the employed approach were assessed and found to be sufficient to obtain realistic models.

Presently, using DFT methods, it is feasible to calculate 100+ nanoparticles of ˜140 atoms, but only several nanoparticles with the size of 800+ atoms can be calculated. Larger particles are very challenging to calculate with DFT. The method according to the invention allows one to calculate using formula (1), and with the DFT accuracy, literally billions of homotops of nanoparticles with the size of 3000+ atoms. Additionally, the method of the present invention is more powerful than similar formulas because of the following: 1) The structural characteristics Nᵢ in the formula directly reflect non-local structural features (for example, the number of heteroatomic bonds in the whole nanoparticle); and 2) The energetic parameters εi are shown for several examples not to depend significantly on the nanoparticle size at a given composition;

Preferably one or more of the following terms are added to formula (1) in order to describe additional effects or to analyze in more detail any of the terms therein. So:

a—a term ε_{INTERFACE}^{A}(x)N_{INTERFACE}^{A} may be added to formula (1) to describe support-induced segregation on the interface,

$${E}_{TOP} = {E}_{0} ( x , N ) + {ɛ}_{BOND}^{A \text{-} B} ( x ) {N}_{BOND}^{A \text{-} B} + {\sum }_{i} {ɛ}_{CORNER , i}^{A} ( x ) {N}_{CORNER , i}^{A} + {\sum }_{j} {ɛ}_{EDGE , j}^{A} ( x ) {N}_{EDGE , j}^{A} + {\sum }_{\{ LMN \}} {ɛ}_{\{ LMN \}}^{A} ( x ) {N}_{\{ LMN \}}^{A} + {ɛ}_{INTERFACE}^{A} ( x ) {N}_{INTERFACE}^{A} \qquad ( 2 )$$

wherein
ε_{INTERFACE}^{A}(x) is the energy required for or gained from the exchange of an atom of type A on the NP-support interface with an atom of type B not in contact with the support and with the same coordination number as the atom A (given that N_{BOND}^{A-B} remains constant),
N_{INTERFACE}^{A} is the numbers of atoms of type A on the nanoparticle-support interface.
b—a term ε_{LAYER}(x)N_{LAYER} may be added to formula (1) to describe alloys with layered structure,

$${E}_{TOP} = {E}_{0} ( x , N ) + {ɛ}_{BOND}^{A \text{-} B} ( x ) {N}_{BOND}^{A \text{-} B} + {\sum }_{i} {ɛ}_{CORNER , i}^{A} ( x ) {N}_{CORNER , i}^{A} + {\sum }_{j} {ɛ}_{EDGE , j}^{A} ( x ) {N}_{EDGE , j}^{A} + {\sum }_{\{ LMN \}} {ɛ}_{\{ LMN \}}^{A} ( x ) {N}_{\{ LMN \}}^{A} + {ɛ}_{LAYER} ( x ) {N}_{LAYER} \qquad ( 3 )$$

wherein
ε_{LAYER}(x) is the energy associated with the formation of monometallic layers of atoms,
N_{LAYER}=Σ_{LAYERS}|nₖ^{A}−nₖ^{B}| is a structural parameter defining the arrangement of atoms in monometallic layers, where nₖ^{A} and nₖ^{B} are the numbers of atoms A and atoms B, respectively, in layer k of a NP and the sum is taken over all layers,

Preferably the values of ε_{BOND}^{A-B}(x), ε_{CORNER,i}^{A}(x), ε_{EDGE,j}^{A}(x) and ε_{{LMN}}^{A}(x) are calculated by fitting them with total energy E_{ES} values of various reference homotops of a reference nanoparticle.

Preferably the total energy E_{ES} values are calculated by density functional theory methods.

Preferably the electronic structure calculations used for fitting of formula (1) include the presence of adsorbates, in order to account for the reaction atmosphere.

Preferably the steps of generating a plurality of homotops and the step of determining the representative homotop are done with a random walk using the Metropolis Monte-Carlo algorithm. The method according to the invention can be also combined with other techniques for global optimization (for example, evolutionary algorithms) in order to obtain the lowest energy structures. However, random walk using Metropolis Monte-Carlo algorithm is required for simulations at a given non-zero temperature.

Preferably the random walk includes a multiple exchange algorithm that allows the exchange of N different pairs of atoms between one generated homotop and the next generated homotop, where N follows the probability distribution p(N)˜N^{-x} with 1≦x≦2. This makes it possible to overcome very big energy barriers that exist in the configurational space of the nanoparticle.

In general, the proposed energy expressions are extendable to account for other contributions, due to e.g. NP-support or NP-adsorbate interactions. This makes the presented method very promising for studies of bimetallic NPs with experimentally accessible sizes in experimentally relevant conditions.

### BRIEF DESCRIPTION OF THE DRAWINGS

Other advantages and features of the invention can be seen from the following description in which preferred non-limiting embodiments of the invention are described in reference to the attached drawings, where:

FIG. 1 Relative energy contributions (%) to the lowest-energy homotops of Pd₇₀X₇₀ NPs according to the topological energy calculated as εᵢNᵢ/ΣεᵢNᵢ. Since in Pd—Cu the only negative term is ε_{BOND}^{Pd—Cu}, the value of ε_{BOND}^{Pd—Cu}N_{BOND}/ΣεᵢNᵢ exceeds 100%.

FIG. 2 Core, subsurface and surface shells of the lowest-energy Pd₇₀X₇₀ (X=Au, Ag, Cu, Zn) homotops according to density functional calculations. Spatial dimensions of the NPs are also indicated (for Pd₇₀Zn₇₀ the dimensions are given in two directions). Pd atoms are displayed as light grey spheres; atoms X—as dark grey spheres.

FIG. 3 Dependency on the NP composition of a) ES calculated mixing energy per atom, and of the descriptors b) ε_{BOND}^{Au—Pd}, c) ε_{CORNER}^{Au}, d) ε_{EDGE}^{Au}, e) ε_{TERRACE}^{Au} in E_{TOP} for Pd_{140-Y}Au_{Y} (solid line) and Pd_{79-Y}Au_{Y} (dashed line) NPs. Error bars represent 60% confidence intervals.

FIG. 4 Structures of Pd₇₃₂X₇₃₁ (X=Au, Ag, Cu, and Zn) NPs with optimized chemical ordering. Pd atoms are displayed as light grey spheres; elements X—as dark grey spheres.

### DETAILED DESCRIPTION

Chemical ordering in Pd₇₀X₇₀ NPs of fcc structure for X=Au, Ag, Cu and tetragonal L1₀ structure for X=Zn, which are interesting for heterogeneous catalysis applications, has been optimized employing the proposed method. Unsupported transition metal NPs of this size were shown to be representative models for catalytic studies (see S. M. Kozlov and K. M. Neyman, Top. Catal., 2013, 56, 867-873, cited above). In order to ensure finding the lowest-energy homotops, a multiple exchange algorithm was used, which allowed the inventors to overcome very big energy barriers in the configurational space of certain NPs. In principle, one would expect bulk segregation of Pd in all these structures, since Pd has the highest surface energy among the considered metals. Nevertheless, only for Pd—Au and Pd—Ag the inventors found high stability of the segregated structures, while Pd—Cu and Pd—Zn exhibited more complex morphologies. The inventors also performed the fitting of topological energies for Pd_{79-Y}Au_{Y} and Pd_{140-Y}Au_{Y} and found that the E_{TOP} expressions depend much less on the NP size than on the composition. This observation allowed the inventors to apply the topological expressions obtained for Pd₇₀X₇₀ NPs (X=Au, Ag, Cu, and Zn) to the optimization of the chemical ordering in the respective 4.4 nm big Pd₇₃₂X₇₃₁ NPs, illustrating the power of the proposed approach.

### Methodology: Optimization of Chemical Ordering in Nanoalloys

The inventors have observed that in bimetallic NPs A_{Y}B_{N-Y} atoms of one element often prefer to occupy interior sites in the most stable structures, while atoms of the other element tend to stay at low-coordinated surface sites. The formation of heteroatomic bonds and layered structures during the alloying process is also important. To quantify these trends in the present examples of the invention, the inventors considered the following form of topological energies, E_{TOP}, that depend only on the mutual positions of atoms of types A and B within a predetermined lattice,

E_{TOP}=E₀+ε_{BOND}^{A-B}N_{BOND}^{A-B}+ε_{CORNER}^{A}N_{CORNER}^{A}+ε_{EDGE}^{A}N_{EDGE}^{A}+ε_{TERRACE}^{A}N_{TERRACE}^{A}+ε_{LAYER}N_{LAYER} (4).

Formula (4) is a specific case of formula (3). In formula (4), parameter E₀ is required for the fitting to energies E_{ES} of the electronic structure calculations and it is constant for a given particle A_{Y}B_{N-Y}; N_{BOND}^{A-B}—number of heteroatomic bonds (nearest-neighbor A-B pairs of atoms) in the considered structure; N_{CORNER}^{A}, N_{EDGE}^{A}, and N_{TERRACE}^{A} numbers of atoms of type A on corners, edges and terraces, respectively. Other parameters, such as N_{BOND}^{A-A}, N_{BOND}^{B-B} or N_{CORNER}^{B}, N_{EDGE}^{B}, and N_{TERRACE}^{B} as well as N_{INTERIOR}^{A} depend linearly on the employed parameters for a given NP size and composition. Thus, they were not included in the E_{TOP}. The term N_{LAYER}=Σ_{LAYERS}|nⱼ^{A}−nⱼ^{B}| accounts for possible atomic arrangements in monometallic layers and tetragonal distortion. nⱼ^{A} and nⱼ^{B} are the numbers of atoms A and atoms B, respectively, in layer j of a NP and the sum is taken over all layers. |nⱼ^{A}−nⱼ^{B}| is maximal for layers composed entirely of atoms A or B and is close to zero for layers composed of both atoms in equal proportions.

In formula (4) εᵢ are energetic parameters associated with each degree of freedom Nᵢ considered in the topological energy. They are referred to as descriptors. In contrast to parameters in many empirical methods, each descriptor εᵢ has a clear physical meaning. For instance, ε_{BOND}^{A-B} is related to the energy gain caused by the mixing of two metals. For example, the formation (mixing) energy of ordered L1₀ A_{0.5}B_{0.5} bulk alloy from separated bulk A and bulk B is 4ε_{BOND}^{A-B} per atom, since in this alloy each atom forms 8 heteroatomic bonds and each bond connects two atoms. In turn, ε_{CORNER}^{A} is the energy required for or gained from the exchange of an atom of type A on the corner with an atom of type B in the NP interior (given that the number of heteroatomic bonds remains constant). ε_{LAYER} is a descriptor associated with the formation of layers in (tetragonally distorted) L1₀ structure; the latter is favored when ε_{LAYER}<0. For Au—Pd, Ag—Pd and Cu—Pd alloys ε_{LAYER} values were calculated to be zero within statistical accuracy. Hence, the term ε_{LAYER}Σ_{LAYERS}|nⱼ^{A}−nⱼ^{B}| was neglected for description of these materials, which did not affect the accuracy of the E_{TOP} expression. The model Hamiltonian that leads to the topological energy expression (4) for bimetallic nanocrystals with fcc structure is presented in the Electronic Supplementary Information.

For each nanocrystal with a given shape, size and composition, an individual topological energy expression is tailored via fitting the descriptors εᵢ to the DFT total energy E_{ES} values of various homotops of this particular NP (obtained via local geometry optimization at DFT level). This way of fitting leads to a rather high accuracy of this approach compared to e.g. interatomic potentials despite the more complex structure of the latter with many more fitting parameters. Naturally, this way of fitting leads to different topological expressions for nanoparticles of different shape, size and composition. However, since each of these descriptors εᵢ determines certain interactions, changes in their values from system to system directly reflect the underlying changes in material properties.

In the present invention, the inventors calculated DFT energies E_{ES} of 22 to 127 homotops to fit E_{TOP} for every considered NP shape and composition via multiple linear regression. When several structures with the same set of Nᵢ degrees of freedom were present in the fitting set, only the structure with the lowest E_{ES} was taken for the fitting. The electronic structure calculations of E_{ES} for N_{FIT} NP structures required for the fitting is the computationally demanding part of the method. Therefore, one should aim to keep the number of DFT calculations at a minimum. Nevertheless, insufficient size of the fitting set would lead to overfitting and poor statistical accuracy of the obtained descriptors εᵢ. The accuracy can be estimated as 95% confidence intervals via the bootstrap method. This method was applied since it seamlessly takes into account that εᵢ are not independent statistical quantities and may strongly correlate with each other. In practice, descriptors that significantly contribute to E_{TOP} have rather small inaccuracies, while those not crucial for the fitting are determined less accurately. Therefore, the inaccuracy of the latter descriptors does not reflect the inaccuracy of the energy expression as a whole.

The precision of the topological expressions themselves was estimated as twice the residual standard deviation (RSD) δ between E_{ES} and E_{TOP} energies for a set of N_{TEST}≧10 structures not included in the fitting procedure

$$δ = 2 \sqrt{\frac{\sum {( {E}_{ES} - {E}_{TOP} )}^{2} - {( \sum ( {E}_{ES} - {E}_{TOP} ) )}^{2} / {N}_{TEST}}{{N}_{TEST} - 1}}$$

According to this definition, (relative) E_{TOP} values are within δ from the respective (relative) E_{ES} values with >95% probability. In turn, the accuracy (trueness) of the topological energies, ΔE, was estimated as the energy difference between the lowest-energy structure according to the ES calculations and the global minimum structure within the topological energy optimization. Since many homotops yield the same E_{TOP} value but somewhat different E_{ES}, the energy difference ΔE was calculated by the topological expression to avoid any arbitrariness.

Once descriptors in formula (4) for a given system are determined, one may use this formula to perform optimization of the chemical ordering within the predetermined lattice. In the examples of the present invention, the inventors carried out Monte-Carlo simulations with only one kind of moves—simultaneous exchange of n random atoms of element A with n random atoms of element B. The number of atoms to be exchanged was chosen randomly with the probability p(n)˜n^{-3/2}, which yields the probability of single exchange moves for big NPs around 1/ζ(3/2)˜38%, where ζ is the Riemann zeta function. This method makes it possible to overcome very big energy barriers that exist, e.g. in the configurational space of Pd—Zn NPs (see the respective discussion in Pd—Zn section).

The temperature in a Monte-Carlo simulation was chosen in such a way that a system spends <50% of time in the lowest-energy configuration. A configuration of A_{Y}B_{N-Y} NP was considered a global minimum, if a move from it to a lower energy structure failed after 10Y(N-Y) multiple exchange moves. This means that the inventors applied every possible one of Y(N-Y) single exchange moves for the global minimum search with probability of

$$1 - {( 1 - \frac{1}{Y ( N - Y )} )}^{0.38 \times 10 Y ( N - Y )} ∼ 1 - {e}^{- 3.8} = 98 \%$$

and a structure of lower energy could not be found.

Whenever a structure with lower energy than the previously calculated ones was found in Monte-Carlo simulations, its geometry was recorded. Out of these structures N_{TEST} structures with the lowest E_{TOP} energies were calculated by the chosen ES technique, and their ES energies were used to estimate the precision of the topological energy approach employed in the Monte-Carlo simulation. Thus, the test sets included diverse low-energy structures ranging from the predicted global minimum to structures located ˜N_{TEST} multiple exchange moves far from it in the configurational space. If it is wanted to improve the precision δ of the E_{TOP} estimated using this test set, then the test set has to be added to the fitting set and new descriptors are obtained. As a result of the global optimization with the new energy expression, a new test set was generated in the fashion described above and the precision of the new E_{TOP} expression was estimated on the new test set, which had not been included in the fitting.

Such way of fitting allows for a better description of low-energy structures (prevailing in the fitting set). It suits the purpose of optimization focusing on finding the structure with the lowest possible energy. In the cases where calculated high-energy structures are qualitatively different from low-energy homotops, one may consider deliberately removing high-energy structures from the fitting in order to further improve the description of low-energy structures. One of such cases could be alloys of metals with considerably different atomic sizes, where high-energy and low-energy homotops may have notably different geometric structures due to the mechanical stress and concomitant relaxation.

The Monte-Carlo scheme also allows one to estimate thermal energy associated with the Boltzmann population of different homotops for a given NP structure. Thermal energies calculated in such a way (with fixed atomic positions) are used only to inspect the magnitude of chemical disorder at finite temperature and to put precision δ of the proposed approach into perspective. Other contributions to the thermal energy may be much bigger and, thus, more important. Nevertheless, they are not relevant to the analysis performed herein.

In the present examples of the invention, the inventors applied the just outlined method to the optimization of chemical ordering in PdAu, PdAg and PdCu NPs with fcc lattices as well as in PdZn NPs with tetragonally distorted L1₀ lattice. It is important to emphasize that having slightly modified topological energy expression and/or electronic structure calculations one may apply the proposed method to a variety of materials, crystalline structures and reaction conditions. For instance, one may substitute ε_{TERRACE}^{A}N_{TERRACE}^{A} in formula (4) by ε_{{111}}^{A}N_{{111}}^{A} and ε_{{100}}^{A}N_{{100}}^{A} to account separately for segregation on {111} and {100} facets in NPs of certain shapes. Similar modifications can be done to distinguish different kinds of edges and corners. To account for NP-support interactions one may include the term ε_{INTERFACE}^{A}N_{INTERFACE}^{A} in formula (4) to describe support-induced segregation on the interface. In order to account for the reaction atmosphere there is no need to change the E_{TOP} expression at all: It is sufficient to consider the presence of adsorbates in the respective electronic structure calculations.

Pd—Au

Alloys of Au and Pd have been intensively studied due to their numerous actual and potential applications in heterogeneous catalysis. They include H₂O₂ synthesis, CH₄ conversion to methanol, C—C coupling, oxygen reduction reaction, and various hydrogenation and oxidation reactions. According to theoretical predictions the Au-shell Pd-core structure is the most thermodynamically favorable for Pd—Au NPs, while a rich variety of Pd—Au NP structures has been detected in experiment. It is important to note that the surface composition of Pd—Au systems may be altered by adsorbates such as CO and that even single Au or Pd atoms or dimers on the surface may significantly affect the overall catalytic performance of the system.

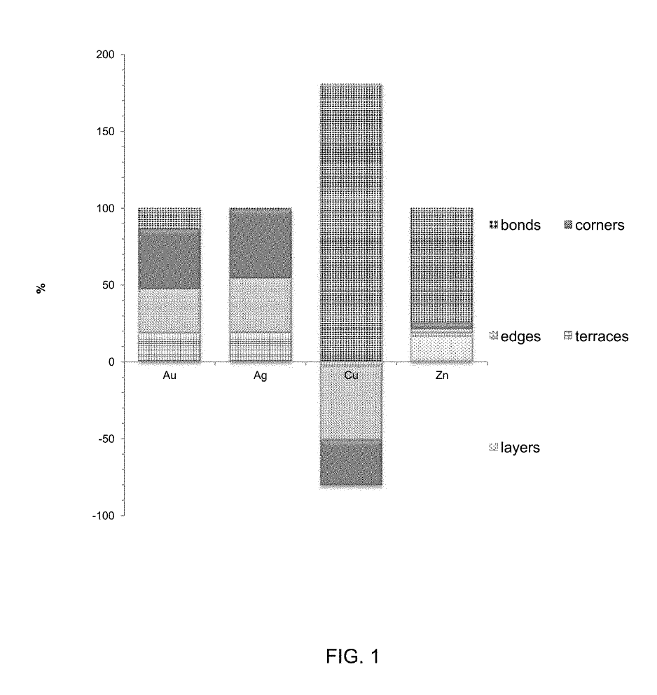

According to the inventor's analysis, the most significant contributions to the E_{TOP} (here and in the following discussion E₀ is subtracted from E_{TOP}) for Pd₇₀Au₇₀ NP come from stabilization of Au atoms on low-coordinated sites (Table 1). The lower coordination number of the site, the bigger is the energy gain: 200 meV for 9-coordinated terrace atoms of Au, 301 meV for 7-coordinated edge atoms, and 404 meV for 6-coordinated corner atoms. The respective contributions to the global minimum energy calculated with the E_{TOP} are 18%, 29%, and 39% (FIG. 1). The energy of a Pd—Au bond is calculated by E_{TOP} to be only ˜13 meV; however, due to the large number of the heteroatomic bonds their contribution to the energy is sizeable, 14%.

TABLE 1
Descriptors^{a} εᵢ in the topological energy expressions E_{TOP} formula
(4) for the Pd₇₀X₇₀ NPs with their precision, δ, and accuracy, ΔE,
values (in meV) and number of structures used for the fitting, N_{FIT}.

| X | Au | Ag | Cu | Zn |
|---|---|---|---|---|
| ε_{BOND}^{Pd-X} | −13₋₆⁺⁴ | −1₋₂⁺² | −26₋₅⁺⁵ | −160₋₄₀⁺⁵² |
| ε_{CORNER}^{X} | −404₋₇₂⁺⁷⁶ | −361₋₆₈⁺⁵⁰ | 95₋₃₃⁺³⁶ | −251₋₃₄₂⁺³¹⁶ |
| ε_{EDGE}^{X} | −301₋₇₇⁺⁵² | −289₋₁₂₉⁺⁷⁸ | 147₋₄₅⁺⁴⁶ | −205₋₂₄₃⁺²⁸⁰ |
| ε_{TERRACE}^{X} | −200₋₆₄⁺⁵² | −163₋₆₄⁺⁴³ | 183₋₄₀⁺⁴² | −90₋₂₃₄⁺²³¹ |
| ε_{LAYER} | — | — | — | −105₋₃₈⁺²⁹ |
| N_{FIT} | 32 | 53 | 127 | 28 |
| δ | 115 | 150 | 360 | 348 |
| ΔE | 26 | 29 | 171 | 0 |

^{a}95% confidence intervals of εᵢ are also given, e.g. −13₋₆⁺⁴ means that the interval is −19 ÷ −9.

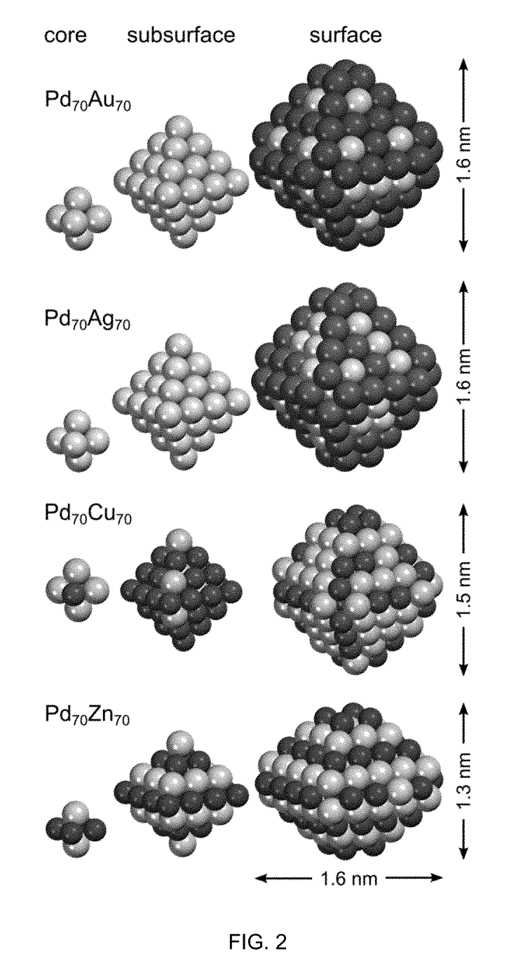

The chemical ordering of the lowest-energy homotop found for Pd₇₀Au₇₀ reflects the magnitude of different terms in the topological energy expression (see FIG. 2). There, Au atoms occupy all the most energetically stable corner and edge positions and the remaining Au atoms are in surface terrace positions. The configuration of Au atoms on terraces may vary from facet to facet tending to maximize the number of Pd—Au bonds. However, in the lowest-energy structure found by DFT there is 260 heteroatomic bonds, while in the global minimum according to E_{TOP} it is 262 (Table 2). This finding reflects the expected presence of other minor contributions (of the order of δ=115 meV) to the E_{ES} that are not accounted for by the E_{TOP}, formula (4).

Pd—Ag

Pd—Ag alloys are studied mostly because of their applications as hydrogenation, fuel cell and other catalysts, sensors and biosensors. Similarly to Pd—Au NPs, theoretical studies' predict Pd-core/Ag-shell structure of Pd—Ag NPs and surface segregation of Ag was also observed in experiment. Interestingly, several experimental studies report homogeneous Pd—Ag alloys or even Pd-shell/Ag-core structures. It was also found that the surface segregation may be affected by the presence of adsorbates such as atomic H.

The inventors have found interactions in Pd₇₀Ag₇₀ to be quite similar to those in Pd₇₀Au₇₀: the lower the coordination number of a site, the more energy is gained when it is occupied by an Ag atom. The most prominent contributions to the topological energy E_{TOP} come from Ag atoms on corners (45%), edges (36%) and terraces (18%) (FIG. 1). The energy of Pd—Ag bonds was calculated to be essentially zero (−1±2 meV); thus, their contribution to E_{TOP} does not exceed 1%.

In line with the topological energy expression for PdAg, the structure of Pd₇₀Ag₇₀ with the lowest E_{ES} has all corner and edge positions occupied by silver atoms. The remaining Ag atoms are located on terraces, whereas the NP interior is composed of solely Pd (FIG. 2). The number of heteroatomic bonds in this structure is only 234, i.e. significantly less than 262 in the global minimum for the respective E_{TOP}. The reason for this difference is the negligible energy associated with N_{BOND}^{Pd—Ag}, which probably compares in magnitude with other contributions to the E_{ES}, not accounted for by the E_{TOP}.

Pd—Cu

A lot of scientific effort has been devoted to Pd—Cu alloys since they catalyze oxygen reduction reaction, O-enhanced water-gas shift reaction (when supported on ceria), formic acid oxidation, water denitrification and several hydrogenation reactions. Early interatomic potential studies revealed two competing effects governing the structure of Pd—Cu NPs: the tendency to maximize the number of heteroatomic bonds and the tendency of Pd or Cu to segregate on the surface. In some studies the enrichment of the surface by Cu or Pd was found to depend on their concentration. In those studies the most energetically stable NP structures also featured higher concentration of surface Cu atoms on corner and edge sites rather than on terrace sites. Experimentally Pd—Cu NPs with Cu-rich surfaces and well mixed ordered or disordered Pd—Cu alloys were characterized. Note that CO-induced surface segregation of Pd was documented for Pd—Cu.

The inventors considered chemical ordering in Pd—Cu with fcc structure since for NPs of few nm it is more stable than bcc structure observed in Pd—Cu bulk. The energetic stability of Pd—Cu NPs comes mainly from the energy of heteroatomic bonds, which is twice of that in Pd—Au NPs (Table 1). Unlike the cases of Pd—Au and Pd—Ag, Cu prefers to stay inside the NP, whereas the surface of Pd₇₀Cu₇₀ is enriched by Pd. The reason is that Pd atoms are bigger than Cu atoms and, therefore, tend to segregate on the surface, where a part of the elastic stress is relieved. However, the employed density functional (as well as other local and gradient-corrected functionals) also favors Pd segregation on the surface, since it predicts the surface energy of Pd (111) to be slightly smaller than the surface energy of Cu (111) in disagreement with experiments. Curiously, the order of stability of Cu in different positions, interior>corner>edge>terrace, does not correlate with the coordination number of Cu in these sites. Since descriptors corresponding to Cu atoms on corner, edge and terrace positions are positive (reflecting that these positions are unstable for Cu with respect to interior ones), their destabilizing contributions to the E_{TOP} of the global minimum are −29, −47 and −3%, respectively. Hence, to counteract that the contribution of the heteroatomic bonds to E_{TOP} formally exceeds 100%.

TABLE 2
Structural properties of the homotops Pd₇₀X₇₀ (X = Au, Ag, Cu, Zn) with the lowest
energies E_{ES} and E_{TOP}. Average coordination numbers of X by X, N^{X—X}, X by Pd,^{a} N^{Pd—X}, and
Pd by Pd, N^{Pd—Pd} are given to facilitate comparison with experimental (e.g. EXAFS) data.

| X | | N_{BOND}^{Pd—X} | N_{CORNER}^{X} | N_{EDGE}^{X} | N_{TERRACE}^{X} | N_{SUBSURFACE}^{X} | N_{CORE}^{X} | N^{X—X} | N^{Pd—X} | N^{Pd—Pd} |
|---|---|---|---|---|---|---|---|---|---|---|
| Au | ES | 260 | 24 | 24 | 22 | 0 | 0 | 3.57 | 3.71 | 7.17 |
| | TOP | 262 | 24 | 24 | 22 | 0 | 0 | | | |
| Ag | ES | 234 | 24 | 24 | 22 | 0 | 0 | 3.94 | 3.34 | 7.54 |
| | TOP | 262 | 24 | 24 | 22 | 0 | 0 | | | |
| Cu | ES | 358 | 16 | 17 | 1 | 35 | 1 | 4.20 | 5.11 | 3.69 |
| | TOP | 382 | 12 | 14 | 8 | 34 | 2 | | | |
| Zn ^{b} | ES = | 422 | 16 | 14 | 16 | 20 | 4 | 2.57 | 6.03 | 3.54 |
| | TOP | | | | | | | | | |

^{a}For NPs with 1:1 composition, the average coordination number of X by Pd equals the average coordination number of Pd by X;
^{b} The same structure yields both the lowest E_{ES} and E_{TOP} for Pd₇₀Zn₇₀; in this structure Σ_{LAYERS}|nᵢ^{Zn} − nᵢ^{Pd}| equals to 136.

The descriptor value for Pd—Cu bonds, −26₋₅⁺⁵ meV/bond, corresponds to the binding energy of −104₋₂₀⁺²⁰ meV per atom in (fcc or bcc) Pd—Cu bulk, which agrees with the experimental value of −114 meV per atom for the bcc alloy.

The homotop with the lowest E_{ES} of the Pd₇₀Cu₇₀ NP exhibits matryoshka-like (also called onion- or multishell-like) arrangement with Pd-rich surface shell, Cu-rich subsurface shell and Pd-rich core. This chemical ordering allows the formation of 358 heteroatomic bonds, while the number of Cu atoms is kept low on the surface, especially on terraces. The structure of the global minimum according to the E_{TOP} features even more heteroatomic bonds, 382, more Cu atoms on terraces and less Cu on edges and corners.

Pd—Zn

Bimetallic Pd—Zn is actively studied (often in the form of surface alloys) because of its catalytic activity in (reverse) water-gas shift and hydrogenation reactions as well as potential application as selective and highly stable catalysts for methanol steam reforming. However, the employment of Pd—Zn catalysts is complicated by the significant dependence of their properties on the Zn/Pd ratio, NP size and the composition of the subsurface region. Further complications come from strong dependence of the structure and composition of Pd—Zn systems on environmental conditions.

Both bulk and nanoparticulate Pd—Zn are known to have tetragonally distorted L1₀ crystal structure without pronounced surface segregation of any component. Experimental interatomic distances in bulk of 1:1 PdZn are Zn—Zn=Pd—Pd=289 pm and Pd—Zn=222 pm. There, Pd and Zn atoms in a distorted fcc-like lattice form monometallic layers and the distances between adjacent atoms in different layers are shorter than those within the same layer. The clear propensity of Pd₇₀Zn₇₀ NPs to build alternating Pd and Zn layers normal to one of the [001], [010] or [001] directions (equivalent in the fcc lattice) accompanied by NP compression along this direction is revealed by DFT calculations and topological ordering optimizations (FIG. 2). Energy of such compression is properly taken into account by the term ε_{LAYER}N_{LAYER} in formula (4). It noticeably increases the E_{TOP} precision for Pd₇₀Zn₇₀ from 1294 meV to 348 meV. (The accuracy ΔE is 0, even when this term is neglected in the E_{TOP} expression.) For alloys that do not tend to form layered structures, the term ε_{LAYER}N_{LAYER} does not improve the E_{TOP} precision or may be even somewhat detrimental due to overfitting. For instance, for Pd₇₀Cu₇₀ excluding that contribution from E_{TOP} increases its precision of the latter by 16%.

Heteroatomic bonds in Pd—Zn NPs are found to be an order of magnitude stronger than those in the other investigated alloys. This difference reflects the fact that composites of Au, Ag, Cu with Pd are alloys of d-elements, while Zn is an sp-element. Strong heteroatomic Pd—Zn bonds of polar character (the charge separation is estimated to range from Pd^{-0.2}Zn^{-0.2} to Pd^{-0.4}Zn^{+0.4}) result in the prevalence of ordered structures of Pd—Zn in the phase diagram. On the contrary, alloys of d-elements are more prone to exhibit more random crystal structures, where the number of heteroatomic bonds is not maximal. Hence, Pd—Zn is better classified as an intermetallic compound rather than a bimetallic alloy.

In line with these considerations, the dominant E_{TOP} contribution for Pd₇₀Zn₇₀ is given by Pd—Zn bonds. The descriptor ε_{BOND}^{Pd—Zn}=−160₋₄₀⁺⁵² meV yields the alloy formation energy of −640₋₁₆₀⁺²⁰⁸ meV per atom, in agreement with the measured value of −520 meV per atom. Hence, heteroatomic bonds define 75% of the E_{TOP} of the global minimum, while the rest comes mostly from the energy associated with the formation of the layered structure (16%). Despite that the energies of Zn atoms on low-coordinated sites are only slightly smaller than the respective energies of Ag atoms in Pd₇₀Ag₇₀, their overall contribution is rather small (9%) compared to that of Pd—Zn bonds. Since the relative energies of Pd₇₀Zn₇₀ NPs do not strongly depend on the number of low-coordinated Zn atoms (compared to other characteristics), it is hard to accurately fit the respective descriptors. Therefore, the formal statistical inaccuracy of ε_{CORNER}^{Zn}, ε_{EDGE}^{Zn}, and ε_{TERRACE}^{Zn} exceeds 100%. Yet, this does not seem to affect the overall accuracy of the proposed approach, because these descriptors appear to be less important for the description of Pd—Zn NPs. To examine how sensitive the chemical ordering in the obtained global minimum is to the statistical inaccuracy of the descriptors for Pd₇₀Zn₇₀ (Table 1), its chemical ordering was re-optimized with 10 other sets of descriptors. These sets were generated by fixing each one of the 5 descriptors at the lowest or the highest value of its 95% confidence interval and re-fitting all other descriptors using for that the same homotops. Despite substantial variations of descriptors produced in such a way, global optimizations with all these 10 sets yielded the homotop with the same Nᵢ characteristics as the one depicted in FIG. 2.

The structures with the lowest E_{ES} and E_{TOP} are the same for Pd₇₀Zn₇₀ NPs due to the high accuracy of the topological energy expression. They feature the maximum possible number of heteroatomic bonds, 422, for the A₇₀B₇₀ NP of the considered shape. The N_{LAYER} value is also the maximum possible, 136, for this particular stoichiometry and shape. As already mentioned, the energies of Zn atoms on the low-coordinated sites are of minor importance for the determination of the most stable Pd₇₀Zn₇₀ homotops. Hence, the amounts of Zn atoms on various types of low-coordinated sites have intermediate values. All in all, the most energetically stable homotop exhibits the layered L1₀ structure, similar to PdZn bulk. Nevertheless, this structure also exposes Pd atoms on Zn-composed edges, due to the slight excess of Pd for the formation of perfect layered structure. Unlike monolayer thick Pd—Zn films on Pd (111), no zigzag-like structures are seen on {111} facets of Zn₇₀Pd₇₀ particles.

For Pd₇₀Zn₇₀ NP one could construct a homotop apparently very similar to the obtained global minimum by exchanging all Zn atoms with all Pd atoms at once. This homotop has the same number of heteroatomic bonds and the same layered structure as the global minimum, but less Zn atoms on corners and edges and more Zn atoms on terraces. Therefore, its E_{ES} (E_{TOP}) is 1765 meV (1389 meV) higher than that of the global minimum displayed in FIG. 2. Despite the apparent similarity, for the simulation code this homotop looks absolutely different compared to the global minimum structure, since the position of every atom has changed. The transition from one homotop to another via exchange of one random Zn atom with a random Pd atom at a time would go through the configurations with rather small amount of Pd—Zn bonds and, therefore, very high relative energy. It was impossible to overcome the transition state between these two homotops via single exchange moves even at Monte-Carlo simulation temperatures as high as 10000 K. However, the transformation between the discussed homotop and the global minimum does not pose any difficulty when multiple exchange moves are applied, that is, n random atoms are exchanged at a time. This illustrates the efficiency of the employed computational scheme, which ensures that the lowest-energy structures from the Monte-Carlo simulations are indeed the global minima within the studied topological framework.

Thermal Energies

Naturally, a system in thermodynamic equilibrium adopts exclusively its global minimum configuration only at zero Kelvin, while at any finite temperature the presence of other homotops is possible with a probability determined by the Boltzmann factor. The configurational space of Pd₇₀Au₇₀, Pd₇₀Ag₇₀ and Pd₇₀Cu₇₀ NPs features many homotops different from the global minima only by the number of heteroatomic bonds. The energies of these homotops are just slightly higher than the energies of the global minima and hence the population of these homotop states is notable even at relatively low temperatures. Consequently, these homotops can contribute to the thermal energy.

It is very instructive to compare the thermal energy accumulated by chemical (dis-)ordering to the precision δ of the topological expressions (Table 1). For example, the Pd₇₀Au₇₀ NP obtains (homotopic) thermal energy of 115 meV already at ˜140 K. (That is, at this temperature the average energy of the system in the Monte-Carlo simulations is 115 meV above the energy of the global minimum.) Therefore, despite that the structure of Pd₇₀Au₇₀ with the lowest found E_{ES} (FIG. 2) may not yet be the global minimum for the chosen ES computational scheme, it is certainly feasible at 140 K and may serve as a representative model for the NP at this and higher temperatures. In a similar way one gets that the considered lowest-energy structure of the Pd₇₀Ag₇₀ is a representative homotop at ˜360 K, while for Pd₇₀Cu₇₀ this temperature is ˜220 K. Unlike the aforementioned three nanoalloys, PdZn features strong heteroatomic bonds with ε_{BOND}^{Pd—Zn} of 160 meV. Thus, there are not many low-energy homotops around the global minimum. In fact, the second most stable structure has the energy E_{TOP} ˜205 meV higher than the global minimum. Therefore, below 500 K essentially the global minimum structure alone has to be present in the thermodynamic ensemble. Much higher temperatures are required to populate less stable homotop states, so the (homotopic) thermal energy reaches the precision of the topological expression, 348 meV, only at ˜1300 K. Thus, this high temperature is related mostly to the propensity of Pd—Zn to form regular nanostructures and to avoid any disorder, rather than to the low precision of the E_{TOP} for this system. Note that Zn evaporates from Pd—Zn surface alloys at temperatures above 800 K. Therefore, it is safe to assume a very small degree of disorder in experimental samples of Pd—Zn close to the thermodynamic equilibrium.

Mixing Energies

Another way to quantify the binding strength of the metals A and B in A_{Y}B_{N-Y} NPs is by means of their mixing energy (per atom):

E^{MIX}=[NE(A_{Y}B_{N-Y})−YE(A_{N})−(N−Y)E(B_{N})]/N²,

where E(A_{Y}B_{N-Y}) is the total energy of the A_{Y}B_{N-Y} NP and E(A_{N}), E(B_{N}) are the energies of respective monometallic NPs with the same structure optimized with the same plane-wave basis cut-off as the A_{Y}B_{N-Y} NP. Thus, e.g. for Pd₇₀Zn₇₀ the NPs Zn₁₄₀ and Pd₁₄₀ with fcc structure were considered as energy references. According to this definition negative E_{MIX} values mean exothermic mixing. Since the presented approach allows calculating total energies of alloy NPs with precision δ, the respective precision of the calculated mixing energy per atom is δ/N.

TABLE 3
Mixing energies^{a} E^{MIX} (per atom, in meV) of the
Pd₇₀X₇₀ homotops with the lowest calculated energy E_{ES}.

| NP | Pd₇₀Au₇₀ | Pd₇₀Ag₇₀ | Pd₇₀Cu₇₀ | Pd₇₀Zn₇₀ |
|---|---|---|---|---|
| E_{ES}^{MIX} | −109₋₁⁺¹ | −108₋₁⁺¹ | −119₋₃⁺³ | −498₋₂⁺² |
| E_{TOP}^{MIX} | −82₋₁₅⁺¹⁵ | −55₋₁₀⁺¹⁰ | −89₋₁₃⁺¹⁴ | −484₋₁₃₅⁺¹⁰⁰ |

^{a}The 95% confidence intervals for E_{ES}^{MIX} were calculated as δ divided by the number of atoms in the NP; the 95% confidence intervals for E_{TOP}^{MIX} were calculated with the bootstrap analysis.

The mixing energies (per atom) of the homotops with the lowest energy E_{ES}, calculated using the respective topological expression and DFT are presented in Table 3. The magnitudes of ES mixing energies are found to be ˜110 meV for Pd—Au, Pd—Ag and Pd—Cu NPs, while for Pd—Zn it is almost 500 meV. The magnitudes of E_{TOP}^{MIX} energies resemble the respective E_{ES}^{MIX} values, except the case of Pd—Ag, for which E_{TOP}^{MIX} is almost twice smaller than E_{ES}^{MIX}. The reason is that the topological energy expression for Pd—Ag assigns almost zero energy to the heteroatomic Pd—Ag bonds and consequently predicts their essentially vanishing contribution to the mixing energy. In the rather similar Pd₇₀Au₇₀ NP heteroatomic bonds are responsible for 30% of the mixing energy calculated using E_{TOP}, which can explain the 33% difference between E_{TOP}^{MIX} for Pd—Au and Pd—Ag.

Dependency of Descriptors on the Composition and the Size of Nanoparticles

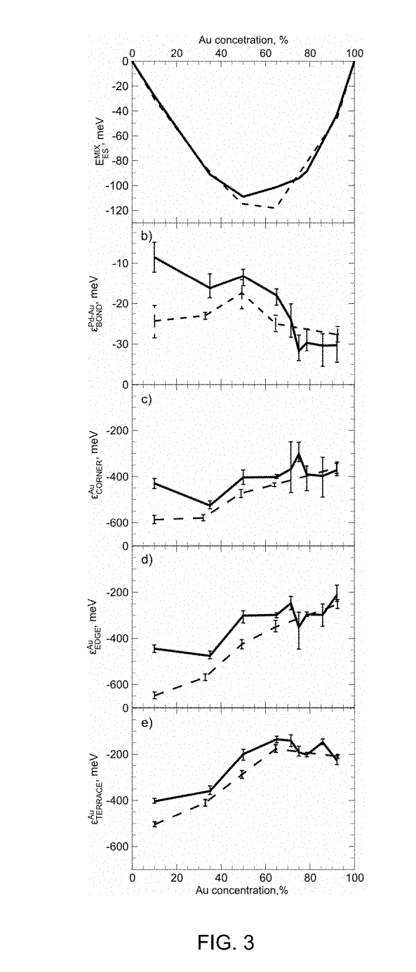

For practical purposes it is very important to know if descriptors obtained for one system can also be used to represent a slightly different system. For instance, one may wonder if descriptors calculated for smaller NPs yield reasonable results when applied to bigger species, for which ES calculations are unfeasible. To evaluate the dependency of descriptors on the size and the composition of NPs the inventors constructed E_{TOP} expressions and performed optimization of chemical ordering in Pd_{Y}Au_{79-Y} (Y=6, 28, 40, 53, 71) and Pd_{Y}Au_{140-Y} (Y=11, 20, 30, 35, 40, 49, 70, 91, 126) NPs. The results are summarized in FIG. 3, where the error bars represent 60% confidence intervals of the εᵢ calculated via the bootstrap analysis. Note that if such confidence intervals for two εᵢ values do not overlap, the probability that these descriptors are not different is less than ((1−0.6)/2)²=4%.

The first observation is that the descriptors (and the mixing energies) significantly depend on the composition of the NPs. That is, the binding in Pd-rich Pd—Au NPs is quite different from that in Au-rich NPs. The latter feature stronger heteroatomic bonds, but less stable gold atoms on surface sites compared to Pd-rich NPs. These differences are probably related to the gradual changes in the electronic structure and average interatomic distances in the NPs with growing Au content. In most cases quantitative changes of the descriptors do not cause qualitative changes in the NP ordering. The only exception is that at very low Au concentrations Au atoms seem to prefer to occupy edges rather than corners of the Pd—Au NPs. This effect is more pronounced for Pd_{Y}Au_{79-Y} than for Pd_{Y}Au_{140-Y} NPs. The change in the relative stability of corner and edge positions for Au is reflected in the structure of the respective global minima.

Nevertheless, Pd—Au NPs prepared by galvanic displacement expose Au atoms on corners rather than on edges. However, according to the inventor's calculations corners are the most stable positions for Au only at moderate and high Au concentrations. The inconsistency between the presented and experimental results may also be due to kinetic limitations in the experimental setup or deficiencies of the employed exchange-correlation density functional.

One notices a rather limited dependency of the descriptors εᵢ and the mixing energies per atom on the NP size. Especially at high Au concentrations, differences between εᵢ values for Pd_{Y}Au_{79-Y} and Pd_{Y}Au_{140-Y} are barely visible and they are often within the statistical accuracy of the calculations. However, at lower Au content the binding was found to be slightly stronger in the smaller NPs. In numerous cases it was shown that many (physical) properties of NPs bigger than 1.5 nm already depend rather smoothly on their size and start to converge to a certain value. Hence, it is probable that the descriptors calculated for Pd_{Y}Au_{140-Y} as well as for other Pd₇₀X₇₀ NPs may serve as a reasonable approximation for descriptors of bigger NPs or, at least, they will lead to qualitatively correct chemical ordering, when applied to bigger NPs. At the same time, descriptors may not work satisfactorily for very small bimetallic clusters, where the quantum nature of interatomic interaction is expected to be notable. The inventor's findings suggest that it is more important to use descriptors tailored for a particular composition than for a particular size.

One may ask, to what extent applications of the present topological method can be limited to such high-symmetry “magic” shapes of bimetallic crystallites, as truncated octahedral ones discussed so far. To address this question the inventors optimized the chemical ordering in a fcc NP Pd₆₁Au₆₁ of just C_{3ν} symmetry with a shape reminiscent of typical shapes of supported Pd NPs. The individual topological descriptors, the overall picture of interactions as well as the chemical ordering in Pd₆₁Au₆₁ are very similar to those of the highly symmetric truncated octahedral NP Pd₇₀Au₇₀. The accuracy ΔE and precision δ values of the E_{TOP} expressions for Pd₆₁Au₆₁ and Pd₇₀Au₇₀ are also very close. These findings strongly suggest that the method is applicable to reliably describe chemical ordering also in nanocrystallites with rather unsymmetrical shapes.

Extrapolation to the 4.4 nm Large Nanoparticles

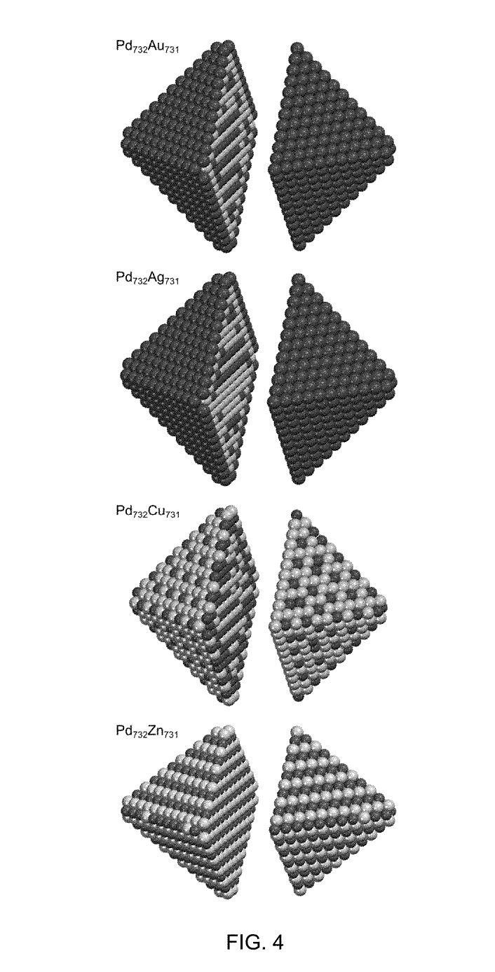

Benefiting from the rather moderate dependency of descriptors on NP size, it was possible to apply the descriptors calculated for Pd₇₀X₇₀ NPs to bigger ˜4.4 nm Pd₇₃₂X₇₃₁ NPs as an illustrative example (see FIG. 4). The shape of these NPs is chosen to mimic the shape of Pd₇₀X₇₀ NPs, i.e. featuring small {100} facets composed of only four atoms. To simulate NPs with bigger {100} facets one would need to calculate the descriptor for X atoms on {100} terraces, which are absent in the M₁₄₀ models. Using the proposed E_{TOP} expression the inventors were able to perform efficient simulations of such ˜4.4 nm NPs with the speed of >10⁷ Monte-Carlo steps per hour on one Intel 2.66 GHz processor.

Both Pd₇₃₂Au₇₃₁ and Pd₇₃₂Ag₇₃₁ NPs have surfaces covered by Au and Ag, respectively. In turn, their subsurface shells are composed mostly of Pd atoms and only two Au or three Ag atoms, which allows the maximization of the number of heteroatomic bonds. Consequently, the cores of the NPs have stoichiometries of Pd₃₃₂Au₁₅₇ and Pd₃₃₃Ag₁₅₆. In order to maximize the number of heteroatomic bonds these Pd_{0.68}X_{0.32} cores also develop L1₀-like structure with partially formed layers of Au or Ag in Pd. The structure of the Pd—Cu NPs is more complicated due to two competing tendencies: maximization of N_{BOND}^{Pd—Cu} and bulk segregation of Cu. As a result, the surface shell has a stoichiometry of Pd₄₁₂Cu₁₆₀ and exhibits abundant Cu monomers as well as occasionally present Cu dimers on terraces and edges. Each corner of the NP has two Cu atoms on the opposite vertices of the small {100} facet. The subsurface shell of the NP is enriched in Cu (stoichiometry Pd₈₇Cu₃₁₅). Finally, the NP core has almost 1:1 stoichiometry, Pd₂₃₃Cu₂₅₆, and again features layer-like structure. As for the global minimum of Pd₇₃₂Zn₇₃₁, quite expectedly, it has almost a bulk-cut structure similarly to the Pd₇₀Zn₇₀ case.

Summary

The inventors have developed a method to optimize chemical ordering in bimetallic NPs using an energy expression related to topological degrees of freedom, E_{TOP}. This expression depends on the topology of bonds between the atoms composing the NP, but not on the explicit coordinates of these atoms. Using this approach the inventors optimized the chemical ordering in truncated octahedral Pd_{Y}Au_{79-Y} and Pd_{Y}Au_{140-Y} NPs as well as in Pd₇₀Ag₇₀ and Pd₇₀Cu₇₀ NPs with fcc lattices and Pd₇₀Zn₇₀ with L1₀ lattice; the chemical ordering in the fcc nanocrystal Pd₆₁Au₆₁ with a less symmetric shape has been also determined. This approach can be applied to bimetallic NPs of any given lattice type, up to the point, when the structure becomes disordered, e.g. at higher temperatures.

For every NP size and composition the energetic parameters (descriptors) in the E_{TOP} expression were fitted to the energies of more than 20 NP structures obtained via density functional calculations. The precision of the topologic description tailored in such a way (i.e. their ability to predict results of the electronic structure calculations) was 115-360 meV for Pd₇₀X₇₀ NPs (X=Au, Ag, Cu and Zn) and the accuracy of the E_{TOP} was at least twice better. For the Pd—Au, Pd—Ag, and Pd—Cu NPs the precision of the topological approach is comparable to the thermal energy associated with the population of low-energy homotops at temperatures of 140-360 K. Therefore, even if some of the lowest-energy structures mentioned above are not exactly the lowest-energy homotops (according to electronic structure calculations), they are representative homotops at very moderate temperatures.

A very useful advantage of the proposed approach is that the descriptors εᵢ in the E_{TOP} expression have a clear physical meaning, e.g. the energy of heteroatomic bonds or the relative energy of X atoms on terrace, edge or corner positions of the NP (interior positions being the reference). Thus, the overall binding energy is inherently a sum of contributions from particular structural features. In turn, changes of these contributions from system to system reflect changes in their properties. Analyzing the structure of the topological energy expression the inventors were able to get valuable insights into the binding in Pd—Au, Pd—Ag, Pd—Cu, and Pd—Zn nanoalloys. Available experimental formation energies of bulk 1:1 PdCu and PdZn agree well with the descriptor values ε_{BOND}^{Pd—X} of heteroatomic bonds for Pd₇₀Cu₇₀ and Pd₇₀Zn₇₀ NPs, respectively. The analysis of descriptors for Pd_{Y}Au_{79-Y} and Pd_{Y}Au_{140-Y} NPs showed a notable dependency on the composition of the NPs, but much smaller dependency on their size. This allows one to use descriptors based on electronic structure calculations of relatively small NPs of e.g. 140 atoms to optimize chemical ordering in bigger species formed of thousands of atoms. Hence, the inventors applied their method to describe the chemical ordering in large Pd₇₃₂X₇₃₁ (X=Au, Ag, Cu and Zn) NPs, which are beyond the scale of conventional density functional calculations.

The optimization of Pd—Au and Pd—Ag NPs with E_{TOP} yields Au and Ag atoms preferentially occupying positions with lower coordination numbers. The energy gain due to the formation of heteroatomic bonds is rather small for these materials and plays a secondary role in the determination of the NP ordering. On the contrary, the energy of heteroatomic bonds is the driving force for the alloying of Cu and Pd. In this case, the stability of Cu atoms is the highest inside the NP and the lowest on NP terraces. These two effects lead to the matryoshka-like structure of the lowest-energy Pd₇₀Cu₇₀ homotop, which has the surface shell enriched with Pd, the subsurface region enriched with Cu and the core composed mostly of Pd.

Unlike bimetallic Pd—Au, Pd—Ag, and Pd—Cu alloys formed by d-elements, the binding in intermetallic Pd—Zn involves the interaction of a noble d-metal with an sp-element. The result is a much higher energy gain due to the formation of Pd—Zn bonds and a much higher (in magnitude) mixing energy of Pd—Zn NPs compared to other considered nanoalloys. The preferential occupation of any particular type of sites by Zn atoms is much less important for the NP structure and energy in this case. The structure of the most energetically stable homotop is very close to the cut from bulk Pd—Zn with L1₀ crystal structure. Just like the bulk, it features alternating Pd and Zn layers and tetragonal distortion. The term in the E_{TOP} expression related to the formation of such a layered structure turned out to be responsible for 16% of the binding in Pd—Zn NPs.

The proposed method for the optimization of the chemical ordering in bimetallic particles paves the way to atomistic studies of several nanometer big bimetallic crystallites with known lattice structure. Fortunately, the latter can be determined by contemporary experimental techniques. Notably, the present new approach may be straightforwardly augmented to be applicable to heterometallic nanocrystals on a support or in a reaction atmosphere.

Methods

Electronic structure calculations were performed with the periodic plane-wave code VASP. The inventors used the PBE exchange-correlation functional found to be one of the most appropriate common functionals for the description of transition metals. The interaction between valence and core electrons was treated within the projector augmented wave approach. To moderate computational expenditures the inventors carried out calculations with the 250-280 eV energy cut-off of plane-wave basis sets, which yielded results very close to those obtained with the cut-off 415 eV. The one-electron levels were smeared by 0.1 eV using the first-order method of Methfessel and Paxton; finally, converged energies were extrapolated to the zero smearing. Calculations were performed only at the Γ-point in the reciprocal space. All atoms were allowed to move (relax) during the geometry optimization until forces on them became less than 0.2 eV/nm. The minimal separation between NPs exceeded 0.7 nm, at which the interaction between adjacent NPs was found to be negligible.

1- Method of manufacturing a binary metallic nanoparticle (AₓB₁₋ₓ)_{N} comprising:
[a] determining the representative homotop for each of a plurality of binary metallic nanoparticles (AₓB₁₋ₓ)_{N} with different compositions AₓB₁₋ₓ, numbers of atoms N or shapes and at a given temperature, by:
[a1] selecting one of said plurality of binary metallic nanoparticles;
[a2] generating a plurality of homotops of the nanoparticle of step [a1];
[a3] calculating an energy of the generated homotops of step [a2] using formula (1):
$${E}_{TOP} = {E}_{0} ( x , N ) + {ɛ}_{BOND}^{A \text{-} B} ( x ) {N}_{BOND}^{A \text{-} B} + {\sum }_{i} {ɛ}_{CORNER , i}^{A} ( x ) {N}_{CORNER , i}^{A} + {\sum }_{j} {ɛ}_{EDGE , j}^{A} ( x ) {N}_{EDGE , j}^{A} + {\sum }_{\{ LMN \}} {ɛ}_{\{ LMN \}}^{A} ( x ) {N}_{\{ LMN \}}^{A} \qquad ( 1 )$$
wherein
E₀(x, N) is constant for a given particle (AₓB₁₋ₓ)_{N},
ε_{BOND}^{A-B}(x) is related to an energy gain caused by the mixing of both metals A, B,
N_{BOND}^{A-B} is a number of heteroatomic bonds;
ε_{CORNER,i}^{A}(x) is an energy required for or gained from an exchange of an atom of type A on a corner of type i of the nanoparticle with an atom of type B in an interior of the nanoparticle, given that N_{BOND}^{A-B} remains constant,
ε_{EDGE,j}^{A}(x) is an energy required for or gained from an exchange of an atom of type A on an edge of type j of the nanoparticle with an atom of type B in the nanoparticle interior, given that N_{BOND}^{A-B} remains constant,
ε_{{LMN}}^{A}(x) is an energy required for or gained from an exchange of an atom of type A on a terrace on a nanoparticle facet with Miller indices {LMN} with an atom of type B in the nanoparticle interior, given that N_{BOND}^{A-B} remains constant,
N_{CORNER,i}^{A}, N_{EDGE,j}^{A}, and N_{{KLM}}^{A} are numbers of atoms of type A on corners of type i, edges of type j and terraces on nanoparticle facets with Miller indices {LMN}, respectively;
[a4] determining the representative homotop of the nanoparticle of step [a1],
[a5] repeating steps [a1] to [a4] for each of the plurality of binary metallic nanoparticles,
[b] determining the physical and/or chemical properties of the resulting representative homotops,
[c] selecting one of said representative homotops having the desirable combination of composition, number of atoms and shape, and
[d] manufacturing of the corresponding binary metallic nanoparticle, wherein the manufacturing includes forming the nanoparticle according to the selected combination of composition, number of atoms and shape.

2- Method according to claim 1, wherein the manufacturing includes forming the nanoparticle by using at least one of molecular beams, chemical reduction, thermal decomposition of transition-metal complexes, ion implantation, electrochemical synthesis, radiolysis, sonochemical synthesis, biosynthesis, co-deposition of two metals on a support, co-precipitation of two metals from a solution or annealing.

3- Method according to claim 2, wherein the annealing step is performed at a predetermined annealing temperature and on a support which is thermally stable at said annealing temperature.

4- Method according to claim 2, wherein the annealing step is performed at a predetermined annealing temperature and surrounded by ligands that are thermally stable at said annealing temperature.

5- Method according to claim 1, wherein a term ε_{INTERFACE}^{A}(x)N_{INTERFACE}^{A} is added to formula (1) to describe support-induced segregation on an interface,
$${E}_{TOP} = {E}_{0} ( x , N ) + {ɛ}_{BOND}^{A \text{-} B} ( x ) {N}_{BOND}^{A \text{-} B} + {\sum }_{i} {ɛ}_{CORNER , i}^{A} ( x ) {N}_{CORNER , i}^{A} + {\sum }_{j} {ɛ}_{EDGE , j}^{A} ( x ) {N}_{EDGE , j}^{A} + {\sum }_{\{ LMN \}} {ɛ}_{\{ LMN \}}^{A} ( x ) {N}_{\{ LMN \}}^{A} + {ɛ}_{INTERFACE}^{A} ( x ) {N}_{INTERFACE}^{A} \qquad ( 2 )$$
wherein
ε_{INTERFACE}^{A}(x) is an energy required for or gained from an exchange of an atom of type A on the nanoparticle-support interface with an atom of type B not in contact with the support and with the same coordination number as the atom A, given that N_{BOND}^{A-B} remains constant, and
N_{INTERFACE}^{A} is a number of atoms of type A on the nanoparticle-support interface.

6- Method according to claim 1, wherein a term ε_{LAYER}(x)N_{LAYER} is added to formula (1) to describe alloys with a layered structure,
$${E}_{TOP} = {E}_{0} ( x , N ) + {ɛ}_{BOND}^{A \text{-} B} ( x ) {N}_{BOND}^{A \text{-} B} + {\sum }_{i} {ɛ}_{CORNER , i}^{A} ( x ) {N}_{CORNER , i}^{A} + {\sum }_{j} {ɛ}_{EDGE , j}^{A} ( x ) {N}_{EDGE , j}^{A} + {\sum }_{\{ LMN \}} {ɛ}_{\{ LMN \}}^{A} ( x ) {N}_{\{ LMN \}}^{A} + {ɛ}_{LAYER} ( x ) {N}_{LAYER} \qquad ( 3 )$$
wherein
ε_{LAYER}(x) is an energy associated with a formation of monometallic layers of atoms, and
N_{LAYER}=Σ_{LAYERS}|nₖ^{A}−nₖ^{B}| defines an arrangement of atoms in monometallic layers, where nₖ^{A} and nₖ^{B} are numbers of atoms A and atoms B, respectively, in layer k of a nanoparticle and a sum is taken over all layers.

7- Method according to claim 1, wherein values of ε_{BOND}^{A-B}(x), ε_{CORNER,i}^{A}(x), ε_{EDGE,j}^{A}(x) and ε_{{LMN}}^{A}(x) are calculated by fitting them with total energy E_{ES} values of various reference homotops of a reference nanoparticle.

8- Method according to claim 7, wherein said total energy E_{ES} values are calculated by density functional theory method.

9- Method according to claim 7, wherein electronic structure calculations used for fitting of formula (1) include a presence of adsorbates, in order to account for a reaction atmosphere.

10- Method according to claim 1, wherein the generating of step [a2] and the determining of step [a4] are done with a random walk using the Metropolis Monte-Carlo algorithm.

11- Method according to claim 10, wherein the random walk includes a multiple exchange algorithm that allows an exchange of N different pairs of atoms between one generated homotop and the next generated homotop, where N follows the probability distribution p(N)˜N^{-x} with 1≦x≦2.

12- Method for determining a representative homotop of a binary metallic nanoparticle (AₓB₁₋ₓ)_{N} with a given composition AₓB₁₋ₓ, number of atoms N and shape, and at a given temperature, comprising:
generating a plurality of homotops;
calculating an energy of the generated homotops using formula (1):
$${E}_{TOP} = {E}_{0} ( x , N ) + {ɛ}_{BOND}^{A \text{-} B} ( x ) {N}_{BOND}^{A \text{-} B} + {\sum }_{i} {ɛ}_{CORNER , i}^{A} ( x ) {N}_{CORNER , i}^{A} + {\sum }_{j} {ɛ}_{EDGE , j}^{A} ( x ) {N}_{EDGE , j}^{A} + {\sum }_{\{ LMN \}} {ɛ}_{\{ LMN \}}^{A} ( x ) {N}_{\{ LMN \}}^{A} \qquad ( 1 )$$
wherein
E₀(x, N) is constant for a given particle (AₓB₁₋ₓ)_{N},
ε_{BOND}^{A-B}(x) is related to an energy gain caused by mixing of both metals A, B,
N_{BOND}^{A-B} is a number of heteroatomic bonds;
ε_{CORNER,i}^{A}(x) is an energy required for or gained from an exchange of an atom of type A on a corner of type i of the nanoparticle with an atom of type B in the interior of the nanoparticle, given that N_{BOND}^{A-B} remains constant,
ε_{EDGE,j}^{A}(x) is an energy required for or gained from an exchange of an atom of type A on an edge of type j of the nanoparticle with an atom of type B in the nanoparticle interior, given that N_{BOND}^{A-B} remains constant,
ε_{{LMN}}^{A}(x) is an energy required for or gained from an exchange of an atom of type A on the terrace on a nanoparticle facet with Miller indices {LMN} with an atom of type B in the nanoparticle interior, given that N_{BOND}^{A-B} remains constant, and
wherein N_{CORNER,i}^{A}, N_{EDGE,j}^{A}, and N_{{KLM}}^{A} are numbers of atoms of type A on corners of type i, edges of type j and terraces on nanoparticle facets with Miller indices {LMN}, respectively, and determining the representative homotop.

13- Method according to claim 12, wherein a term ε_{INTERFACE}^{A}(x)N_{INTERFACE}^{A} is added to formula (1) to describe support-induced segregation on an interface,
$${E}_{TOP} = {E}_{0} ( x , N ) + {ɛ}_{BOND}^{A \text{-} B} ( x ) {N}_{BOND}^{A \text{-} B} + {\sum }_{i} {ɛ}_{CORNER , i}^{A} ( x ) {N}_{CORNER , i}^{A} + {\sum }_{j} {ɛ}_{EDGE , j}^{A} ( x ) {N}_{EDGE , j}^{A} + {\sum }_{\{ LMN \}} {ɛ}_{\{ LMN \}}^{A} ( x ) {N}_{\{ LMN \}}^{A} + {ɛ}_{INTERFACE}^{A} ( x ) {N}_{INTERFACE}^{A} \qquad ( 2 )$$
wherein
ε_{INTERFACE}^{A}(x) is an energy required for or gained from an exchange of an atom of type A on the nanoparticle-support interface with an atom of type B not in contact with the support and with the same coordination number as the atom A, given that N_{BOND}^{A-B} remains constant, and
N_{INTERFACE}^{A} is a number of atoms of type A on the nanoparticle-support interface.

14- Method according to claim 12, wherein a term ε_{LAYER}(x)N_{LAYER} is added to formula (1) to describe alloys with a layered structure,
$${E}_{TOP} = {E}_{0} ( x , N ) + {ɛ}_{BOND}^{A \text{-} B} ( x ) {N}_{BOND}^{A \text{-} B} + {\sum }_{i} {ɛ}_{CORNER , i}^{A} ( x ) {N}_{CORNER , i}^{A} + {\sum }_{j} {ɛ}_{EDGE , j}^{A} ( x ) {N}_{EDGE , j}^{A} + {\sum }_{\{ LMN \}} {ɛ}_{\{ LMN \}}^{A} ( x ) {N}_{\{ LMN \}}^{A} + {ɛ}_{LAYER} ( x ) {N}_{LAYER} \qquad ( 3 )$$
wherein
ε_{LAYER}(x) is an energy associated with a formation of monometallic layers of atoms, and
N_{LAYER}=Σ_{LAYERS}|nₖ^{A}−nₖ^{B}| defines an arrangement of atoms in monometallic layers, where nₖ^{A} and nₖ^{B} are numbers of atoms A and atoms B, respectively, in layer k of a nanoparticle and a sum is taken over all layers.

15- Method according to claim 12, wherein values of ε_{BOND}^{A-B}(x), ε_{CORNER,i}^{A}(x), ε_{EDGE,j}^{A}(x) and ε_{{LMN}}^{A}(x) are calculated by fitting them with the total energy E_{ES} values of various reference homotops of a reference nanoparticle.

16- Method according to claim 15, wherein said total energy E_{ES} values are calculated by density functional theory method.

17- Method according to claim 15, wherein electronic structure calculations used for fitting of formula (1) include a presence of adsorbates, in order to account for a reaction atmosphere.

18- Method according to claim 12, wherein the generating of a plurality of homotops and the determining of the representative homotop are done with a random walk using the Metropolis Monte-Carlo algorithm.

19- Method according to claim 18, wherein the random walk includes a multiple exchange algorithm that allows an exchange of N different pairs of atoms between one generated homotop and the next generated homotop, where N follows the probability distribution p(N)˜N^{-x} with 1≦x≦2.
